(19) United States
(12) Patent Application Publication
(10) Pub. No.: US 2015/0171324 A1
(43) Pub. Date: Jun. 18, 2015

(54) METHOD OF MANUFACTURING VARIABLE RESISTANCE NONVOLATILE MEMORY DEVICE, AND VARIABLE RESISTANCE NONVOLATILE MEMORY DEVICE

(71) Applicant: Panasonic Corporation, Osaka (JP)

(72) Inventors: Takumi Mikawa, Shiga (JP); Atsushi Himeno, Osaka (JP); Hideaki Murase, Osaka (JP)

(73) Assignee: Panasonic Corporation, Osaka (JP)

(21) Appl. No.: 14/372,142

(22) PCT Filed: Jan. 10, 2013
(86) PCT No.: PCT/JP2013/000048

§ 371 Date: Jul. 14, 2014

(30) Foreign Application Priority Data
Jan. 19, 2012 (JP) 2012-009435

(51) Int. Cl. H01L 45/00

(52) U.S. Cl. CPC H01L 45/1608; H01L 45/12; H01L 45/146

(57) ABSTRACT

A method of manufacturing a variable resistance nonvolatile memory device includes: forming, above a substrate, a metal-semiconductor-metal (MSM) diode element; forming a variable resistance element on the MSM diode element; forming a first oxygen barrier layer which covers a side wall of a semiconductor layer of the MSM diode element, and does not cover at least part of a side wall of a variable resistance layer of the variable resistance element; and oxidizing the side wall of the variable resistance layer which is exposed without being covered by the first oxygen barrier layer.

### TECHNICAL FIELD

The present invention relates to a method of manufacturing a variable resistance nonvolatile memory device including a variable resistance element having a resistance value which changes in response to an application of a voltage, and to the variable resistance nonvolatile memory device.

### BACKGROUND ART

Recent years have seen increasing high performance in electronic devices such as mobile information devices and information appliances following the development of digital technology. With the increased high performance in these electronic devices, miniaturization and increase in speed of semiconductor memory devices used are rapidly advancing. Among these, application for large-capacity nonvolatile memories represented by a flash memory is rapidly expanding. In addition, as a next-generation new-type nonvolatile memory to replace the flash memory, research and development on a variable resistance nonvolatile memory element (ReRAM: resistive random access memory) which uses what is called a variable resistance element is advancing. Here, a variable resistance element refers to an element which possesses certain properties allowing a resistance value thereof to change reversibly in response to an electric signal (electric pulse), and which is further capable of storing information corresponding to a resistance value in a nonvolatile manner.

As an example of a large-capacity nonvolatile memory including a variable resistance element, a nonvolatile memory device including a variable resistance element is proposed, for example as disclosed in Patent Literature (PTL) 1. The variable resistance element is formed by stacking a plurality of variable resistance layers. Each of the variable resistance layers comprises a transition metal oxide having a different degree of oxygen deficiency. A change in resistance can be stabilized by selectively causing an oxidation-reduction reaction at an interface between a variable resistance layer having a low degree of oxygen deficiency and an electrode which is in contact with the variable resistance layer having a low degree of oxygen deficiency.

On the other hand, as an example of a large-capacity nonvolatile memory device including the variable resistance element, a cross-point nonvolatile memory device has been proposed as disclosed in PTL 2, for example. In the nonvolatile memory device, a variable resistance element is used as a memory unit, and a diode element is used as a switching element. A memory cell is formed with a series circuit of the variable resistance element and the diode element. The variable resistance element is formed by disposing the variable resistance layer between an upper electrode and a lower electrode. In the variable resistance layer, information is stored due to a change in an electric resistance caused by an electrical stress. The diode element is a two-terminal nonlinear element having a nonlinear current-voltage characteristic in which a current changes inconstantly with respect to a voltage change. Current flows bidirectionally in the nonlinear element when the memory cell is rewritten. Thus, the nonlinear element has, for example, a current-voltage characteristic which is bidirectionally symmetric and nonlinear. With the above-described configuration, it is possible to pass a current having a current density greater than or equal to 30 kA/cm² that is necessary to perform rewriting on a variable resistance element. This makes it possible to increase the capacity of the nonvolatile memory.

### CITATION LIST

### Patent Literature

### [PTL 1]

International Publication No. 2008/149484

### [PTL 2]

Japanese Unexamined Patent Application Publication No. 2006-203898

### SUMMARY OF INVENTION

### Technical Problem

The above-described conventional variable resistance nonvolatile memory device has a following problem. In the case where a variable resistance layer has a stacked structure including a first variable resistance layer and a second variable resistance layer which has a lower degree of oxygen deficiency than the first variable resistance layer, an initial resistance value (a resistance value immediately after manufacturing) upon the first application of an electric pulse is larger than a resistance value obtained in a high resistance state at the time of a normal change in resistance. Thus, applying an electric pulse in this initial state does not change resistance in each of variable resistance layers. To achieve a stable resistance change characteristic, an initial breakdown needs to be performed in which an electric pulse (an initial breakdown voltage) is applied to the variable resistance layer in the initial state to form a conductive path in a part of the second variable resistance layer. When the initial breakdown is performed, an unnecessary voltage is distributed to a transistor and a parasitic resistance component other than the variable resistance element. Thus, it is necessary to apply to the variable resistance element sufficient voltage as the initial breakdown voltage.

In view of this, a proposal is made in which a side wall of the first variable resistance layer of the variable resistance element is insulated by oxidation. With this, an active area of the first variable resistance layer is reduced. This increases a density of a current that flows from the first variable resistance layer to the second variable resistance layer, and a conductive path is easily formed in the second variable resistance layer. As a result, it is possible to lower the initial breakdown voltage and reduce application time of the initial breakdown voltage. Note that, the active area is an effective area which affects an electric characteristic of a variable resistance element, and is a largest cross-sectional area in a path through which a current flows in the variable resistance element.

However, a diode element which does not need to be oxidized is oxidized when oxidizing the side wall of the variable resistance element. This results in a deterioration of driving capability of a diode element, which is problematic.

The present invention aims at solving the above-described problem, and has as an object to provide: a method of manufacturing a variable resistance nonvolatile memory device which can lower the initial breakdown voltage, reduce the application time of the initial breakdown voltage, and prevent the deterioration of the driving capability of the diode element; and the variable resistance nonvolatile memory device.

### Solution to Problem

In order to achieve the above-described object, a method of manufacturing a variable resistance nonvolatile memory device according to an aspect of the present invention includes: forming, above a substrate, a diode element including a semiconductor layer; forming a variable resistance element by stacking, on the diode element, a first electrode, a variable resistance layer, and a second electrode in this order; forming a first oxygen barrier layer which covers a side wall of the semiconductor layer of the diode element, and does not cover at least part of a side wall of the variable resistance layer of the variable resistance element; and oxidizing the side wall of the variable resistance layer which is exposed without being covered by the first oxygen barrier layer.

### Advantageous Effects of Invention

In a method of manufacturing a variable resistance nonvolatile memory device according to an aspect of the present invention, a first oxygen barrier layer is formed to cover a side wall of a semiconductor layer of a diode element. With this, it is possible to prevent the diode element from oxidizing when oxidizing a side wall of a variable resistance layer of a variable resistance element. This makes it possible to prevent the deterioration of driving capability of the diode element.

### BRIEF DESCRIPTION OF DRAWINGS

FIG. 1 is a cross-sectional view showing a configuration of a variable resistance nonvolatile memory device according to Embodiment 1.

FIG. 2A is a cross-sectional view showing a method of manufacturing the variable resistance nonvolatile memory device according to Embodiment 1.

FIG. 2B is a cross-sectional view showing the method of manufacturing the variable resistance nonvolatile memory device according to Embodiment 1.

FIG. 2C is a cross-sectional view showing the method of manufacturing the variable resistance nonvolatile memory device according to Embodiment 1.

FIG. 2D is a cross-sectional view showing the method of manufacturing the variable resistance nonvolatile memory device according to Embodiment 1.

FIG. 2E is a cross-sectional view showing the method of manufacturing the variable resistance nonvolatile memory device according to Embodiment 1.

FIG. 2F is a cross-sectional view showing the method of manufacturing the variable resistance nonvolatile memory device according to Embodiment 1.

FIG. 2G is a cross-sectional view showing the method of manufacturing the variable resistance nonvolatile memory device according to Embodiment 1.

FIG. 2H is a cross-sectional view showing the method of manufacturing the variable resistance nonvolatile memory device according to Embodiment 1.

FIG. 2I is a cross-sectional view showing the method of manufacturing the variable resistance nonvolatile memory device according to Embodiment 1.

FIG. 3 is a cross-sectional view showing a configuration of a variable resistance nonvolatile memory device according to Embodiment 2.

FIG. 4A is a cross-sectional view showing a method of manufacturing the variable resistance nonvolatile memory device according to Embodiment 2.

FIG. 4B is a cross-sectional view showing the method of manufacturing the variable resistance nonvolatile memory device according to Embodiment 2.

FIG. 4C is a cross-sectional view showing the method of manufacturing the variable resistance nonvolatile memory device according to Embodiment 2.

FIG. 4D is a cross-sectional view showing the method of manufacturing the variable resistance nonvolatile memory device according to Embodiment 2.

FIG. 5 is a cross-sectional view showing a configuration of a conventional variable resistance nonvolatile memory device.

FIG. 6A is a cross-sectional view showing a method of manufacturing the conventional variable resistance nonvolatile memory device.

FIG. 6B is a cross-sectional view showing the method of manufacturing the conventional variable resistance nonvolatile memory device.

FIG. 6C is a cross-sectional view showing the method of manufacturing the conventional variable resistance nonvolatile memory device.

FIG. 6D is a cross-sectional view showing the method of manufacturing the conventional variable resistance nonvolatile memory device.

FIG. 6E is a cross-sectional view showing the method of manufacturing the conventional variable resistance nonvolatile memory device.

FIG. 6F is a cross-sectional view showing the method of manufacturing the conventional variable resistance nonvolatile memory device.

FIG. 6G is a cross-sectional view showing the method of manufacturing the conventional variable resistance nonvolatile memory device.

FIG. 7 is a graph showing a relationship between a side wall oxidation amount of a variable resistance element and an initial breakdown voltage (initial breakdown voltage characteristic) in the conventional variable resistance nonvolatile memory device.

FIG. 8 is a transmission electron microscope (TEM) image showing a cross-sectional view of the conventional variable resistance nonvolatile memory device.

FIG. 9 is a graph showing an I-V characteristic of an MSM diode element of the conventional variable resistance nonvolatile memory device.

### DESCRIPTION OF EMBODIMENTS

### Underlying Knowledge Forming Basis of the Present Invention

First, a problematic point found by the inventor of the present invention that occurs with a conventional variable resistance nonvolatile memory device is described, and then embodiments of the present invention are described. Note that, while the following description is intended as an aid in understanding the present invention, the following various conditions and the like are not meant to limit the present invention.

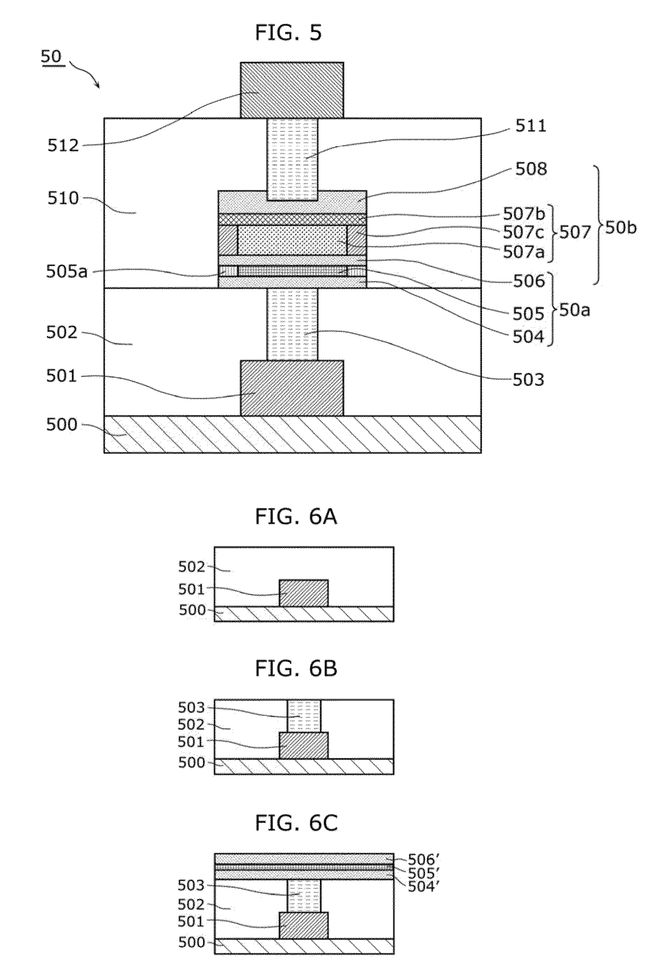

FIG. 5 is a cross-sectional view showing a configuration of the conventional variable resistance nonvolatile memory device. In a variable resistance nonvolatile memory device 50 shown in FIG. 5, a first line 501 and a first interlayer insulating layer 502 are formed on a substrate 500. A first contact plug 503 is formed which penetrates the first interlayer insulating layer 502, and the first contact plug 503 is electrically connected to the first line 501. Furthermore, a metal-semiconductor-metal (MSM) diode element 50a is formed to cover the first contact plug 503, and a variable resistance element 50b is formed on the MSM diode element 50a.

The MSM diode element 50a includes: a lower electrode 504 electrically connected to the first contact plug 503; an upper electrode 506 disposed opposite the lower electrode 504; and a semiconductor layer 505 disposed between the lower electrode 504 and the upper electrode 506. The semiconductor layer 505 includes a nitrogen-deficient silicon nitride film (SiNₓ).

The variable resistance element 50b includes: a lower electrode 506 (shared with the upper electrode 506 of the MSM diode element 50a); an upper electrode 508 disposed opposite the lower electrode 506; and a variable resistance layer 507 disposed between the lower electrode 506 and the upper electrode 508.

Here, the variable resistance layer 507 has a stacked structure including a first variable resistance layer 507a and a second variable resistance layer 507b. The first variable resistance layer 507a and the second variable resistance layer 507b each comprise a transition metal oxide which includes oxygen-deficient tantalum oxide (TaOₓ, 0<x<2.5) as a main component. A second transition metal oxide included in the second variable resistance layer 507b has a degree of oxygen deficiency lower than a degree of oxygen deficiency of a first transition metal oxide included in the first variable resistance layer 507a.

As shown in FIG. 5, a third variable resistance layer 507c having a lower degree of oxygen deficiency than the first variable resistance layer 507a is formed on a side wall (outer periphery part) of the first variable resistance layer 507a. In this manner, the third variable resistance layer 507c having a relatively high resistance value is disposed on the side wall of the first variable resistance layer 507a which has a relatively low resistance value. Thus, an area (active area) of the first variable resistance layer 507a in the plane direction is smaller than an area of an electrode region of the upper electrode 508. As a result, a density of a current which flows from the first variable resistance layer 507a to the second variable resistance layer 507b increases, and a conductive path is easily formed in the second variable resistance layer 507b. With this, the initial breakdown voltage of the variable resistance nonvolatile memory device 50 can be lowered.

Furthermore, in the variable resistance nonvolatile memory device 50, a second interlayer insulating layer 510 is formed to cover the MSM diode element 50a and the variable resistance element 50b. A second contact plug 511 is formed which penetrates the second interlayer insulating layer 510. The second contact plug 511 is electrically connected to the upper electrode 508 of the variable resistance element 50b. Furthermore, a second line 512 electrically connected to the second contact plug 511 is formed.

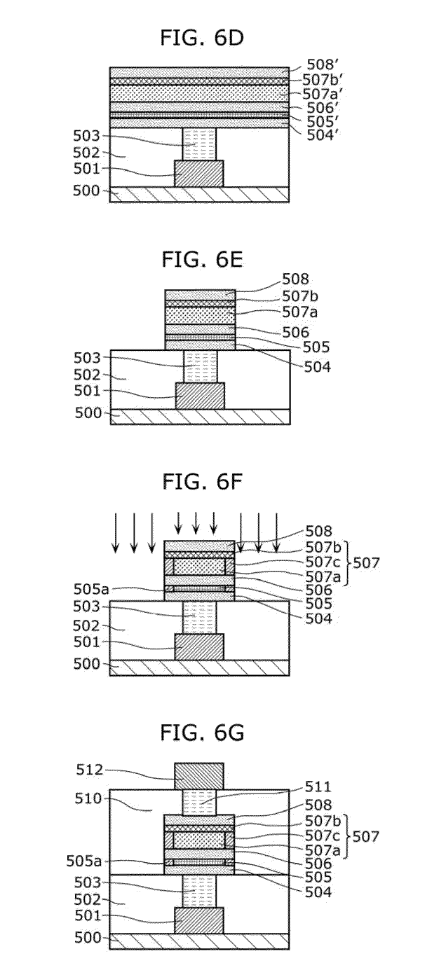

Next, a method of manufacturing the conventional variable resistance nonvolatile memory device 50 is described. Each of FIG. 6A to FIG. 6G is a cross-sectional view showing a method of manufacturing the conventional variable resistance nonvolatile memory device.

First, as shown in FIG. 6A, the first line 501 and the first interlayer insulating layer 502 are formed on the substrate 500.

Subsequently, as shown in FIG. 6B, the first contact plug 503 is formed which penetrates the first interlayer insulating layer 502 and is electrically connected to the first line 501.

Subsequently, as shown in FIG. 6C, a first conductive film 504′ comprising a tantalum nitride, a semiconductor film 505′ including a nitrogen deficient silicon nitride film, and a second conductive film 506′ comprising a tantalum nitride are formed on the first interlayer insulating layer 502 in this order to cover the first contact plug 503.

Subsequently, as shown in FIG. 6D, a first variable resistance film 507a′ and a second variable resistance film 507b′ each comprising a transition metal oxide, and a third conductive film 508′ comprising a noble metal (platinum, iridium, palladium, or the like) are formed in this order.

Subsequently, using a predetermined mask, as shown in FIG. 6E, the third conductive film 508′, the second variable resistance film 5071Y, the first variable resistance film 507a′, the second conductive film 506′, the semiconductor film 505′, and the first conductive film 504′ are each patterned. With this, the upper electrode 508, the second variable resistance layer 507b, the first variable resistance layer 507a, the lower electrode 506 (the upper electrode 506), the semiconductor layer 505, and the lower electrode 504 are formed.

Subsequently, as shown in FIG. 6F, the variable resistance element 50b is annealed in an oxygen atmosphere, which oxidizes the side wall of the first variable resistance layer 507a. With this, the third variable resistance layer 507c is formed on the side wall of the first variable resistance layer 507a.

Subsequently, as shown in FIG. 6G, the second interlayer insulating layer 510 is formed to cover the variable resistance element 50b.

Subsequently, the second contact plug 511 is formed which penetrates the second interlayer insulating layer 510 and is electrically connected to the upper electrode 508. Lastly, the second line 512 is formed which is electrically connected to the second contact plug 511.

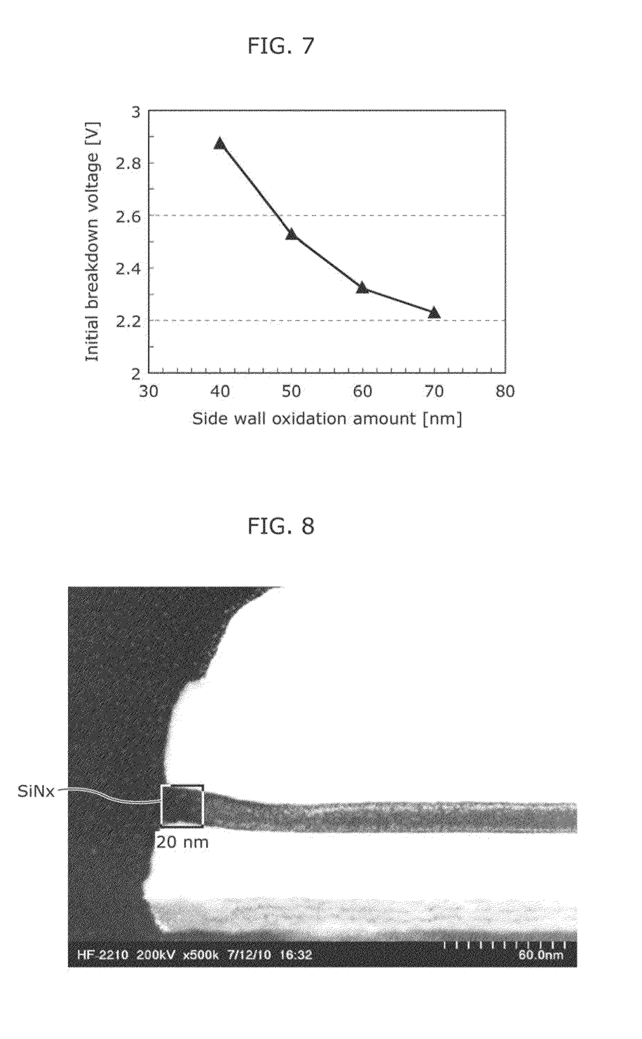

FIG. 7 is a graph showing a relationship between a side wall oxidation amount and an initial breakdown voltage (initial breakdown voltage characteristic) in the conventional variable resistance nonvolatile memory device. In the graph shown in FIG. 7, the horizontal axis indicates an amount the side wall of a variable resistance layer is oxidized (a side wall oxidation amount) in a process shown in FIG. 6F, and the vertical axis indicates a magnitude of the initial breakdown voltage of the variable resistance element. Here, the side wall oxidation amount is an estimated amount obtained using a monitor by measuring, using an optical film thickness gauge, an oxidation amount which proceeds in a vertical direction (a direction toward a depth direction from a surface of the side wall of the variable resistance layer). Note that, an actual side wall oxidation amount can be affected by various factors. FIG. 7 indicates that an active area of the variable resistance element reduces with an increase in the side wall oxidation amount, and an advantageous effect of lowering of the initial breakdown voltage is produced.

However, the above-described conventional manufacturing method has a problem that a side wall 505a of the semiconductor layer 505 of the MSM diode element 50a not in need of oxidation is oxidized in the process shown in FIG. 6F, resulting in a deterioration of driving capability of the MSM diode element 50a. FIG. 8 is a TEM image showing a cross-sectional view of the conventional variable resistance nonvolatile memory device. As shown in FIG. 8, the side wall of the semiconductor layer of the MSM diode element is discolored approximately 20 nm, indicating oxidation.

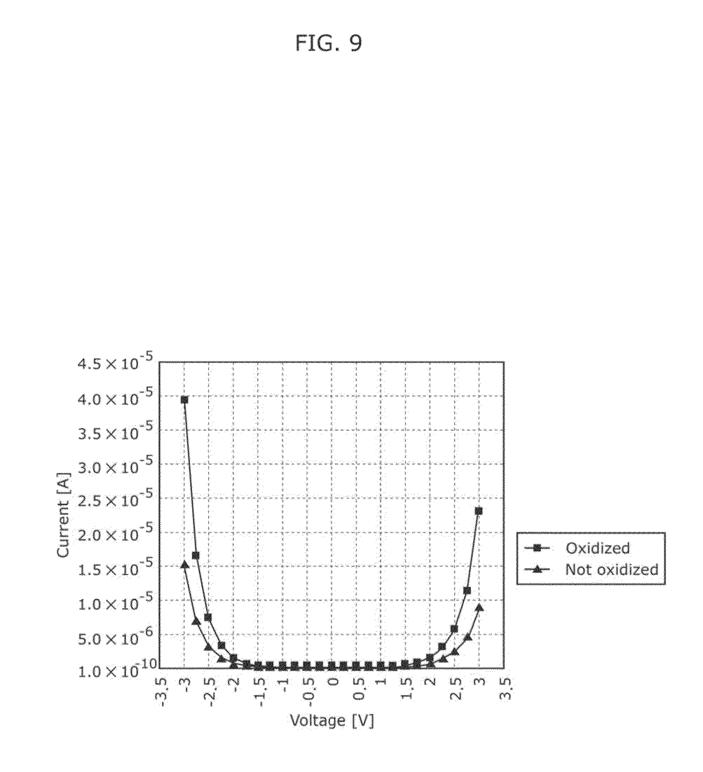

FIG. 9 is a graph showing an I-V characteristic of the MSM diode element of the conventional variable resistance nonvolatile memory device. As shown in FIG. 9, an MSM diode element can pass a current bidirectionally, and has a characteristic of passing a small current in a low voltage region, and passing an exponentially increased current with an increase in a voltage. In FIG. 9, data indicated by a black triangle is data of the case where the side wall of the semiconductor layer of the MSM diode element is oxidized, and data indicated by a black square is data of the case where the side wall of the semiconductor layer of the MSM diode element is not oxidized. Comparison of these data indicates that a current capacity of the MSM diode element is generally deteriorated due to an oxygen anneal performed in the process shown in FIG. 6F. In particular, an on-current is reduced. More specifically, the data indicates that an active area of the semiconductor layer reduces by oxidation of the side wall of the semiconductor layer of the MSM diode element, resulting in a deterioration of the driving capability of the MSM diode element. This means that required currents cannot be provided when the initial breakdown and rewriting of the variable resistance element are performed, implying that an operation of the variable resistance nonvolatile memory device becomes significantly unstable. Note that, the above-described phenomenon, that is, the deterioration of the driving capability of the diode element due to oxidation of the side wall of the semiconductor layer of the MSM diode element is not limited to the MSM diode element. A similar problem, that is, the deterioration of the driving capability of the diode element also occurs in a variable resistance memory cell including a diode element, such as a p-n junction diode element, a Schottky diode element, or the like, which includes a rectifying layer comprising an easily oxidizable material, due to the decrease in the active area caused by the oxidation of the rectifying layer.

A p-n junction diode element or a Schottky diode element is a single direction diode. Thus, when a driving current decreases, the driving current can be increased using a different approach, such as a change in concentration in a p-n junction portion, a change in a work function, or the like. On the other hand, an MSM diode is a bidirectional diode where a change in a work function results in a change in a ratio between an on-current and an off-current of a driving current. Thus, such an approach cannot be adopted. In view of this, it is assumed that the present invention produces an advantageous effect more effectively for an MSM diode element.

The present invention solves the above-described problem, and prevents the diode element from oxidizing when oxidizing the side wall of the variable resistance layer of the variable resistance element, and prevents deterioration of the driving capability of a diode element.

A method of manufacturing a variable resistance nonvolatile memory device according to an aspect of the present invention includes: forming, above a substrate, a diode element including a semiconductor layer; forming a variable resistance element by stacking, on the diode element, a first electrode, a variable resistance layer, and a second electrode in this order; forming a first oxygen barrier layer which covers a side wall of the semiconductor layer of the diode element, and does not cover at least part of a side wall of the variable resistance layer of the variable resistance element; and oxidizing the side wall of the variable resistance layer which is exposed without being covered by the first oxygen barrier layer.

According to this aspect, the side wall of the semiconductor layer of the diode element is covered by the first oxygen barrier layer, and thus it is possible to prevent the side wall of the semiconductor layer from oxidizing when oxidizing the side wall of the variable resistance layer. This makes it possible to simultaneously achieve two advantageous effects which are (i) lowering of the initial breakdown voltage and reduction in application time of the initial breakdown voltage, and (ii) prevention of the deterioration of the driving capability of the diode element. With this, it is possible to sufficiently provide currents that are required when the initial breakdown, rewriting, and the like are performed on the variable resistance element, and stabilize operations of the variable resistance nonvolatile memory device.

For example, in the method of manufacturing a variable resistance nonvolatile memory device according to an aspect of the present invention, the first oxygen barrier layer may prevent the side wall of the semiconductor layer of the diode element from oxidizing.

According to this aspect, the first oxygen barrier layer is formed. This makes it possible to prevent the side wall of the semiconductor layer of the diode element from oxidizing.

For example, in the method of manufacturing a variable resistance nonvolatile memory device according to an aspect of the present invention, the side wall of the variable resistance layer may be insulated in the oxidizing of the side wall of the variable resistance layer.

According to this aspect, the side wall of the variable resistance layer is insulated. This makes it possible to lower the initial breakdown voltage and reduce the application time of the initial breakdown voltage.

For example, the method of manufacturing a variable resistance nonvolatile memory device according to an aspect of the present invention may further include forming, after the oxidizing of the side wall of the variable resistance layer, a second oxygen barrier layer which covers the side wall of the variable resistance layer.

According to this aspect, the second oxygen barrier layer which covers the oxidized side wall of the variable resistance layer is formed. This makes it possible to prevent external oxygen from diffusing into the variable resistance layer. With this, it is possible to reduce variation in the side wall oxidation amount of the variable resistance layer, and stabilize the side wall oxidation amount of the variable resistance layer. The stabilization in the side wall oxidation amount of the variable resistance layer reduces variations in an active area of the variable resistance element narrowed down by the side wall oxidation. Thus, it is possible to reduce variation in a current density at the time of the initial breakdown, allowing for reduction of variation in a magnitude and the application time of the initial breakdown voltage.

For example, in the method of manufacturing a variable resistance nonvolatile memory device according to an aspect of the present invention, the second oxygen barrier layer may prevent external oxygen from diffusing into the side wall of the variable resistance layer.

According to this aspect, the second oxygen barrier layer is formed. This makes it possible to prevent external oxygen from diffusing into the side wall of the variable resistance layer.

For example, in the method of manufacturing a variable resistance nonvolatile memory device according to an aspect of the present invention, the second oxygen barrier layer may further cover the first oxygen barrier layer.

According to this aspect, the side wall of the semiconductor layer of the diode element is doubly covered by the first oxygen barrier layer and the second oxygen barrier layer. This makes it possible to even more reliably prevent external oxygen from diffusing into the semiconductor ayer of the diode element.

For example, the method of manufacturing a variable resistance nonvolatile memory device according to an aspect of the present invention may further include forming an interlayer insulating layer to cover the diode element and the variable resistance element.

According to this aspect, it is possible to form the interlayer insulating layer to cover the diode element and the variable resistance element.

For example, in the method of manufacturing a variable resistance nonvolatile memory device according to an aspect of the present invention, the variable resistance layer formed in the forming of a variable resistance element may include a first variable resistance layer comprising a first metal oxide, and a second variable resistance layer comprising a second metal oxide having a degree of oxygen deficiency lower than a degree of oxygen deficiency of the first metal oxide.

According to this aspect, the variable resistance layer can have a stacked structure including the first variable resistance layer and the second variable resistance layer.

For example, in the method of manufacturing a variable resistance nonvolatile memory device according to an aspect of the present invention, the variable resistance layer may comprise a transition metal oxide or an aluminum oxide.

According to this aspect, the variable resistance layer can comprise a transition metal oxide or an aluminum oxide.

For example, in the method of manufacturing a variable resistance nonvolatile memory device according to an aspect of the present invention, the diode element may be a metal-semiconductor-metal (MSM) diode element formed by: forming a third electrode above the substrate; forming the semiconductor layer on the third electrode; and forming a fourth electrode on the semiconductor layer.

When the diode element includes the MSM diode element as described in this aspect, the driving current can be increased more effectively without changing the ratio between the on-current and the off-current of the driving current.

For example, in the method of manufacturing a variable resistance nonvolatile memory device according to an aspect of the present invention, the first electrode and the fourth electrode may be formed as a same electrode which serves as a shared electrode.

According to this aspect, the first electrode and the fourth electrode can be the same electrode to be shared.

A variable resistance nonvolatile memory device according to an aspect of the present invention includes a substrate; a diode element which is formed above the substrate, and includes a semiconductor layer; and a variable resistance element which is formed on the diode element, and includes a variable resistance layer, wherein the variable resistance element includes: a first electrode; a second electrode disposed opposite the first electrode; the variable resistance layer disposed between the first electrode and the second electrode; and a first oxygen barrier layer which covers a side wall of the semiconductor layer of the diode element, and does not cover at least part of a side wall of the variable resistance layer of the variable resistance element, and a region of the side wall of the variable resistance layer of the variable resistance element not covered by the first oxygen barrier layer is insulated.

According to this aspect, the side wall of the semiconductor layer of the diode element is covered by the first oxygen barrier layer, and thus it is possible to prevent the side wall of the semiconductor layer from oxidizing when oxidizing the side wall of the variable resistance layer. Thus, deterioration of the driving capability of the diode element can be prevented. Furthermore, the active area of the variable resistance element is reduced due to the oxidation of the side wall of the variable resistance layer. With this, a leakage current which flows from the variable resistance element to outside is reduced. This makes it possible to lower the initial breakdown voltage and reduce the application time of the initial breakdown voltage.

For example, in the variable resistance nonvolatile memory device according to an aspect of the present invention, the first oxygen barrier layer may prevent the side wall of the semiconductor layer of the diode element from oxidizing.

According to this aspect, the first oxygen barrier layer can prevent the side wall of the semiconductor layer of the diode element from oxidizing.

For example, in the variable resistance nonvolatile memory device according to an aspect of the present invention, the variable resistance element may further include a second oxygen barrier layer which covers the side wall of the variable resistance layer which is oxidized.

According to this aspect, the second oxygen barrier layer which covers the oxidized side wall of the variable resistance layer is formed. This makes it possible to prevent external oxygen from diffusing into the variable resistance layer. With this, it is possible to reduce variation in the side wall oxidation amount of the variable resistance layer, and stabilize the side wall oxidation amount of the variable resistance layer. The stabilization in the side wall oxidation amount of the variable resistance layer reduces variations in an active area of the variable resistance element narrowed down by the side wall oxidation. Thus, it is possible to reduce variation in a current density at the time of the initial breakdown, allowing for reduction of variation in a magnitude and the application time of the initial breakdown voltage.

For example, in the variable resistance nonvolatile memory device according to an aspect of the present invention, the second oxygen barrier layer may prevent external oxygen from diffusing into the side wall of the variable resistance layer.

According to this aspect, the second oxygen barrier layer can prevent external oxygen from diffusing into the side wall of the variable resistance layer.

For example, in the variable resistance nonvolatile memory device according to an aspect of the present invention, the second oxygen barrier layer may further cover the first oxygen barrier layer.

According to this aspect, the side wall of the semiconductor layer of the diode element is doubly covered by the first oxygen barrier layer and the second oxygen barrier layer. This makes it possible to even more reliably prevent external oxygen from diffusing into the semiconductor layer of the diode element.

For example, in the variable resistance nonvolatile memory device according to an aspect of the present invention, an oxide layer may be formed on a surface of the first oxygen barrier layer.

According to this aspect, the oxide layer is formed on the surface of the first oxygen barrier layer by oxidizing the side wall of the variable resistance layer.

For example, in the variable resistance nonvolatile memory device according to an aspect of the present invention, the variable resistance layer may comprise a transition metal oxide or an aluminum oxide.

According to this aspect, the variable resistance layer can comprise the transition metal oxide or the aluminum oxide.

For example, in the variable resistance nonvolatile memory device according to an aspect of the present invention, the variable resistance layer may comprise a transition metal oxide selected from tantalum, hafnium, and zirconium.

According to this aspect, the transition metal oxide selected from tantalum, hafnium, and zirconium is a material which has a good retention characteristic and can operate at high speed. Thus, even when the variable resistance layer comprises a material which requires the initial breakdown, the initial breakdown voltage characteristic can be significantly stabilized.

For example, in the variable resistance nonvolatile memory device according to an aspect of the present invention, the variable resistance layer of the variable resistance element may include a first variable resistance layer comprising a first metal oxide, and a second variable resistance layer comprising a second metal oxide having a degree of oxygen deficiency lower than a degree of oxygen deficiency of the first metal oxide.

According to this aspect, the variable resistance layer can have a stacked structure including the first variable resistance layer and the second variable resistance layer.

For example, in the variable resistance nonvolatile memory device according to an aspect of the present invention, the diode element may be an MSM diode element which includes: a third electrode formed above the substrate; a fourth electrode disposed opposite the third electrode; and the semiconductor layer disposed between the third electrode and the fourth electrode.

When the diode element includes the MSM diode element as described in this aspect, the driving current can be increased more effectively without changing the ratio between the on-current and the off-current of the driving current.

For example, in the variable resistance nonvolatile memory device according to an aspect of the present invention, the first electrode and the fourth electrode may be a same electrode which serves as a shared electrode.

According to this aspect, the first electrode and the fourth electrode can be the same electrode to be shared.

The following describes a variable resistance nonvolatile memory device and a method of manufacturing the same according to an aspect of the present invention with reference to drawings.

Each of embodiments described below shows a general or specific example. The numerical values, shapes, materials, structural elements, the arrangement and connection of the structural elements, steps, the processing order of the steps etc. shown in the following embodiments are mere examples, and therefore do not limit the scope of the present invention. Furthermore, among the structural elements in the following embodiments, structural elements not recited in any one of the independent claims indicating the broadest concept are described as arbitrary structural elements.

Note that, although the embodiments below are described using examples in which diode elements are MSM diode elements, the diode element is not limited to the MSM diode element, as described above. The variable resistance nonvolatile memory device may include another diode element, such as a p-n junction diode element, a Schottky diode element, or the like, which includes a rectifying layer comprising an easily oxidizable material.

### Embodiment 1

### Configuration of Variable Resistance Nonvolatile Memory Device

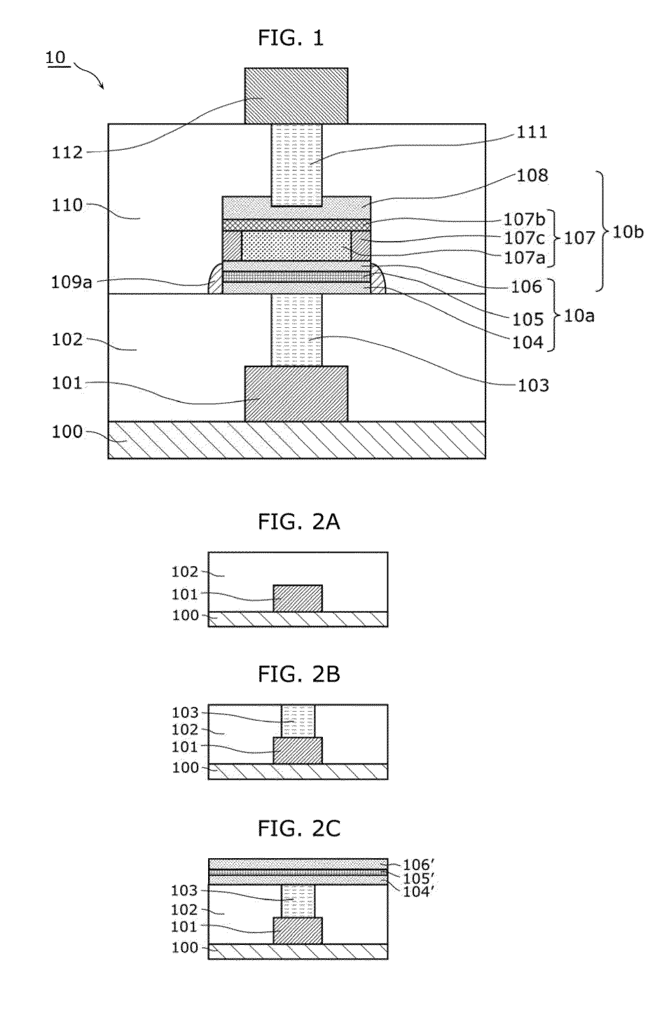

FIG. 1 is a cross-sectional view showing a configuration of a variable resistance nonvolatile memory device according to Embodiment 1. A variable resistance nonvolatile memory device 10 in the figure includes: a substrate 100, a first line 101, a first interlayer insulating layer 102, a first contact plug 103, an MSM diode element 10a, a variable resistance element 10b, a second interlayer insulating layer 110, a second contact plug 111, and a second line 112.

The first line 101 is formed on the substrate 100 on which a transistor and so on are formed. The first line 101 comprises, for example, copper, aluminum, or the like.

The first interlayer insulating layer 102 is formed on the substrate 100 to cover the first line 101. The first interlayer insulating layer 102 comprises, for example, a silicon oxide.

The first contact plug 103 is formed which penetrates the first interlayer insulating layer 102. The first contact plug 103 is electrically connected to the first line 101. The first contact plug 103 comprises, for example, tungsten, copper, or the like.

The MSM diode element 10a includes a lower electrode 104 (included in a third electrode), a semiconductor layer 105, and an upper electrode 106 (included in a fourth electrode) which are stacked in this order. The lower electrode 104 is electrically connected to the first contact plug 103. The upper electrode 106 is disposed opposite the lower electrode 104. The semiconductor layer 105 is disposed between the lower electrode 104 and the upper electrode 106. The lower electrode 104 and the upper electrode 106 each comprise, for example, a tantalum nitride (TaN). The semiconductor layer 105 includes, for example, a nitrogen-deficient silicon nitride film (SiNₓ).

The variable resistance nonvolatile memory device 10 according to this embodiment is characterized in that a first oxygen barrier layer 109a is formed which covers the side wall (outer periphery part) of the semiconductor layer 105 of the MSM diode element 10a, and does not cover at least part of the side wall of a first variable resistance layer 107a (which will be described later). The first oxygen barrier layer 109a needs to provide (i) a function as an oxygen barrier which prevents external oxygen from diffusing into the semiconductor layer 105 and (ii) a function as an insulator which prevents a leakage current from flowing in the side wall of the semiconductor layer 105. The first oxygen barrier layer 109a comprises a material, such as a silicon nitride (SiN), a silicon oxynitride (SiON), or the like, which has both of the above-described functions.

The variable resistance element 10b includes a lower electrode 106 (included in a first electrode), a variable resistance layer 107, and an upper electrode 108 (included in a second electrode) which are stacked in this order. In this embodiment, the lower electrode 106 of the variable resistance element 10b is shared with the upper electrode 106 of the MSM diode element 10a. The upper electrode 108 is disposed opposite the lower electrode 106. The variable resistance layer 107 is disposed between the lower electrode 106 and the upper electrode 108. The upper electrode 108 comprises, for example, a noble metal, such as platinum (Pt), iridium (Jr), or palladium (Pd), or the like.

The variable resistance layer 107 is positioned between the lower electrode 106 and the upper electrode 108, and is a layer having a resistance value that reversibly changes based on an electrical signal applied between the lower electrode 106 and the upper electrode 108. The variable resistance layer 107 is, for example, a layer that reversibly changes between a high resistance state and a low resistance state according to a polarity of a voltage applied between the lower electrode 106 and the upper electrode 108. The variable resistance layer 107 includes at least two layers, namely, the first variable resistance layer 107a connected to the lower electrode 106, and a second variable resistance layer 107b connected to the upper electrode 108 which are stacked.

The first variable resistance layer 107a comprises an oxygen-deficient first metal oxide, and the second variable resistance layer 107b comprises a second metal oxide having a degree of oxygen deficiency lower than a degree of oxygen deficiency of the first metal oxide. A minute local region having a degree of oxygen deficiency that reversibly changes according to an application of an electric pulse is formed in the second variable resistance layer 107b of the variable resistance element 10b. It is assumed that the local region includes a filament including oxygen defect sites.

The first variable resistance layer 107a comprises a first transition metal oxide which includes an oxygen-deficient tantalum oxide (TaOₓ, 0<x<2.5) as a primary component, for example. The second variable resistance layer 107b comprises a second transition metal oxide which includes an oxygen-deficient tantalum oxide (TaO_{y}, x<y) as a primary component, for example. Note that, when the first variable resistance layer 107a and the second variable resistance layer 107b comprise transition metal oxides other than a tantalum oxide, the first variable resistance layer 107a and the second variable resistance layer 107b each comprise a material having, from the stoichiometric composition which exhibits insulating properties, a low degree of oxygen deficiency (i.e., high resistance). As a material included in the variable resistance layer 107, a hafnium (Hf) oxide or a zirconium (Zr) oxide may be used other than the tantalum oxide, for example.

Note that, “degree of oxygen deficiency” refers to the percentage of deficient oxygen with respect to the amount of oxygen included in an oxide of the stoichiometric composition (in the case where there are plural stoichiometric compositions, the stoichiometric composition having the highest resistance value among the stoichiometric compositions) in the metal oxide. Compared to a metal oxide with another composition, a metal oxide having a stoichiometric composition is more stable and has a higher resistance value.

For example, when the metal is tantalum (Ta), the oxide having the stoichiometric composition according to the above definition is Ta₂O₅, and thus can be expressed as TaO_{2.5}. The degree of oxygen deficiency of TaO_{2.5} is 0%, and the degree of oxygen deficiency of TaO_{1.5} becomes: degree of oxygen deficiency=(2.5−1.5)/2.5=40%. Furthermore, a metal oxide having excess oxygen has a degree of oxygen deficiency with a negative value. Note that, in this Description, unless stated otherwise, the degree of oxygen deficiency includes positive values, 0 (zero), and negative values.

An oxide having a low degree of oxygen deficiency has a high resistance value since it is closer to an oxide having a stoichiometric composition, and an oxide having a high degree of oxygen deficiency has a low resistance value since it is closer to a metal included in an oxide.

Note that, an “oxygen content atomic percentage” is a ratio of the number of oxygen atoms to total number of atoms. For example, the oxygen content atomic percentage of Ta₂O₅ is a ratio of oxygen atoms to the total number of atoms (O/(Ta+O)) and is thus 71.4 atm %. This means that an oxygen-deficient tantalum oxide has an oxygen content atomic percentage higher than 0 and lower than 71.4 atm %. For example, when the metal included in the first metal oxide and the metal included in the second metal oxide comprise the same constituent metal, the oxygen content atomic percentage corresponds with the degree of oxygen deficiency. That is to say, when the oxygen content atomic percentage of the second metal oxide is greater than the oxygen content atomic percentage of the first metal oxide, the degree of oxygen deficiency of the second metal oxide is less than the degree of oxygen deficiency of the first metal oxide.

A metal other than tantalum may be used as the metal included in the variable resistance layer 107. As the metal included in the variable resistance layer 107, a transition metal or aluminum (Al) can be used. That is, the variable resistance layer 107 may comprise a transition metal oxide or an aluminum oxide. Tantalum (Ta), titanium (Ti), hafnium (Hf), zirconium (Zr), niobium (Nb), tungsten (W), nickel (Ni), or the like may be used as the transition metal. Since transition metals can assume many different oxidation states, it is possible to achieve different resistance states through oxidation-reduction reactions.

For example, when a hafnium oxide is used, the resistance value of the variable resistance layer 107 can be changed at high-speed and in a stable manner when the composition of the first metal oxide is HfOₓ where x is no less than 0.9 and no more than 1.6, and the composition of the second metal oxide is HfO_{y} where y is greater than x. In this case, the second metal oxide may have a thickness of no less than 3 nm and no more than 4 nm.

Furthermore, when a zirconium oxide is used, the resistance value of the variable resistance layer 107 can be changed at high-speed and in a stable manner when the composition of the first metal oxide is ZrOₓ where x is no less than 0.9 and no more than 1.4, and the composition of the second metal oxide is ZrO_{y} where y is greater than x. In this case, the second metal oxide may have a thickness of no less than 1 nm and no more than 5 nm.

Note that, the first metal included in the first metal oxide and the second metal included in the second metal oxide may be different metals. In this case, the second metal oxide may have a lower degree of oxygen deficiency than the first metal oxide, in other words, may have a higher resistance. By adopting such a configuration, the voltage applied between the lower electrode 106 and the upper electrode 108 in a resistance change is distributed more to the second metal oxide, thereby allowing the oxidation-reduction reactions to occur more easily in the second metal oxide.

Furthermore, when mutually different materials are used for the first metal included in the first metal oxide forming the first variable resistance layer 107a and the second metal included in the second metal oxide forming the second variable resistance layer 107b, the standard electrode potential of the second metal may be lower than the standard electrode potential of the first metal. The standard electrode potential indicates a property in which resistance to oxidation is greater with a higher value. As such, an oxidation-reduction reaction can occur relatively easily in the second metal oxide having a relatively low standard electrode potential. It should be noted that, with regard to the resistance changing phenomenon, it is assumed that the resistance value (degree of oxygen deficiency) changes because an oxidation-reduction reaction occurs in the minute local region formed in the high-resistance second metal oxide and the filament (conductive path) changes.

For example, by using an oxygen-deficient tantalum oxide (TaOₓ) for the first metal oxide and a titanium oxide (TiO₂) for the second metal oxide, a stable resistance changing operation can be achieved. Titanium (standard electrode potential=−1.63 eV) is a material having a lower standard electrode potential than tantalum (standard electrode potential=−0.6 eV). In this manner, by using an oxide of a metal having a lower standard electrode potential than the first metal oxide for the second metal oxide, the oxidation-reduction reaction occurs more easily in the second metal oxide. As other combinations, an aluminum oxide (Al₂O₃) can be used for the second metal oxide that becomes a high resistance layer. For example, an oxygen-deficient tantalum oxide (TaOₓ) may be used for the first metal oxide, and an aluminum oxide (Al₂O₃) may be used for the second metal oxide.

It is assumed that, with regard to the resistance changing phenomenon in the variable resistance layer 107 having the stacked structure, the resistance value changes because an oxidation-reduction reaction occurs in the minute local region formed in the second metal oxide that has high-resistance and the filament (conductive path) inside the local region changes.

In other words, when a voltage that is positive with respect to the lower electrode 106 is applied to the upper electrode 108 connected to the second metal oxide, the oxygen ions in the variable resistance layer 107 are drawn to the second metal oxide side. With this, an oxidation reaction occurs in the minute local region formed in the second metal oxide and the degree of oxygen deficiency decreases. As a result, it is assumed that it becomes difficult for the filament inside the local region to connect, and the resistance value increases.

On the other hand, when a voltage that is negative with respect to the lower electrode 106 is applied to the upper electrode 108 connected to the second metal oxide, the oxygen ions in the second metal oxide are pushed to the first metal oxide side. With this, a reduction reaction occurs in the minute local region formed in the second metal oxide and the degree of oxygen deficiency increases. As a result, it is assumed that it becomes easy for the filament inside the local region to connect, and the resistance value decreases.

The upper electrode 108 connected to the second metal oxide having a lower degree of oxygen deficiency comprises, for example, a material, such as platinum (Pt), iridium (Ir), or palladium (Pd), which has a higher standard electrode potential than the metal included in the second metal oxide and the material included in the lower electrode 106. Moreover, the lower electrode 106 connected to the first metal oxide having a higher degree of oxygen deficiency may comprise, for example, a material, such as tungsten (W), nickel (Ni), tantalum (Ta), titanium (Ti), aluminum (Al), tantalum nitride (TaN), or titanium nitride (TiN), which has a lower standard electrode potential than the metal included in the first metal oxide. The standard electrode potential indicates a property in which resistance to oxidation is greater with a higher value.

In other words, between a standard electrode potential V2 of the upper electrode 108, a standard electrode potential Vr2 of the metal included in the second metal oxide, a standard electrode potential Vr1 of the metal included in the first metal oxide, and a standard electrode potential V1 of the lower electrode 106, the relationships Vᵣ₂<V₂ and V₁<V₂ may be satisfied. Furthermore, the relationship Vr1≧V1 while V2>Vr2 may be satisfied.

With the above configuration, an oxidation-reduction reaction selectively occurs in the second metal oxide in the vicinity of the interface between the upper electrode 108 and the second metal oxide, and the resistance changing phenomenon can be achieved in a stable manner.

A third variable resistance layer 107c is formed on a side wall (outer periphery part) of the first variable resistance layer 107a. The third variable resistance layer 107c comprises a third transition metal oxide which includes an oxygen-deficient tantalum oxide (TaO_{z}, x<z) as a main component. In other words, the third transition metal oxide included in the third variable resistance layer 107c has a degree of oxygen deficiency which is lower than a degree of oxygen deficiency of a transition metal oxide included in the first variable resistance layer 107a. Each of the third variable resistance layer 107c and the first variable resistance layer 107a is in contact with the lower surface of the second variable resistance layer 107b. As described, the third variable resistance layer 107c having a relatively high resistance value is disposed on the side wall of the first variable resistance layer 107a having a relatively low resistance value. Thus, an area (active area) in the plane direction of the first variable resistance layer 107a is small compared to an area of an electrode region of the upper electrode 108. As a result, a density of a current that flows from the first variable resistance layer 107a to the second variable resistance layer 107b increases, and a conductive path is easily formed in the second variable resistance layer 107b. With this, the initial breakdown voltage of the variable resistance nonvolatile memory device 10 can be lowered, and the application time of the initial breakdown voltage can be reduced.

Furthermore, in the variable resistance nonvolatile memory device 10, the second interlayer insulating layer 110 is formed to cover the MSM diode element 10a and the variable resistance element 10b. Note that, the second interlayer insulating layer 110 is formed to indirectly cover, via the first oxygen barrier layer 109a, the MSM diode element 10a. The second contact plug 111 is formed which penetrates the second interlayer insulating layer 110, and the second contact plug 111 is electrically connected to the upper electrode 108 of the variable resistance element 10b. Furthermore, the second line 112 is formed which is electrically connected to the second contact plug 111.

(Manufacturing Method)

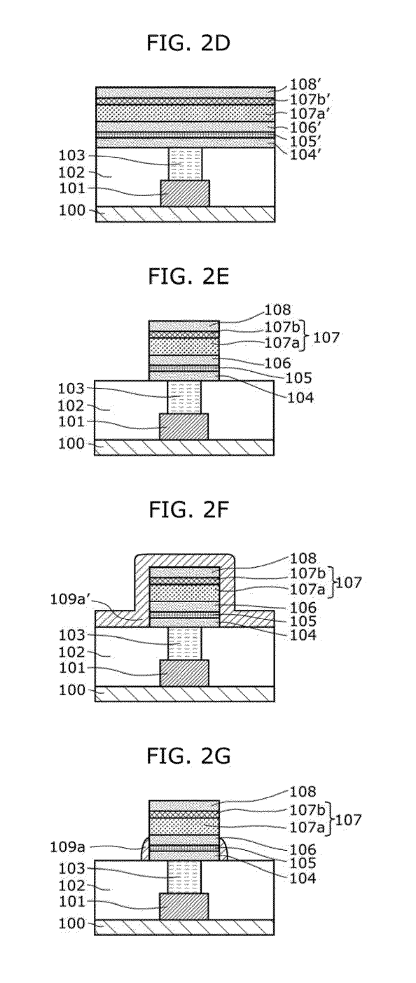

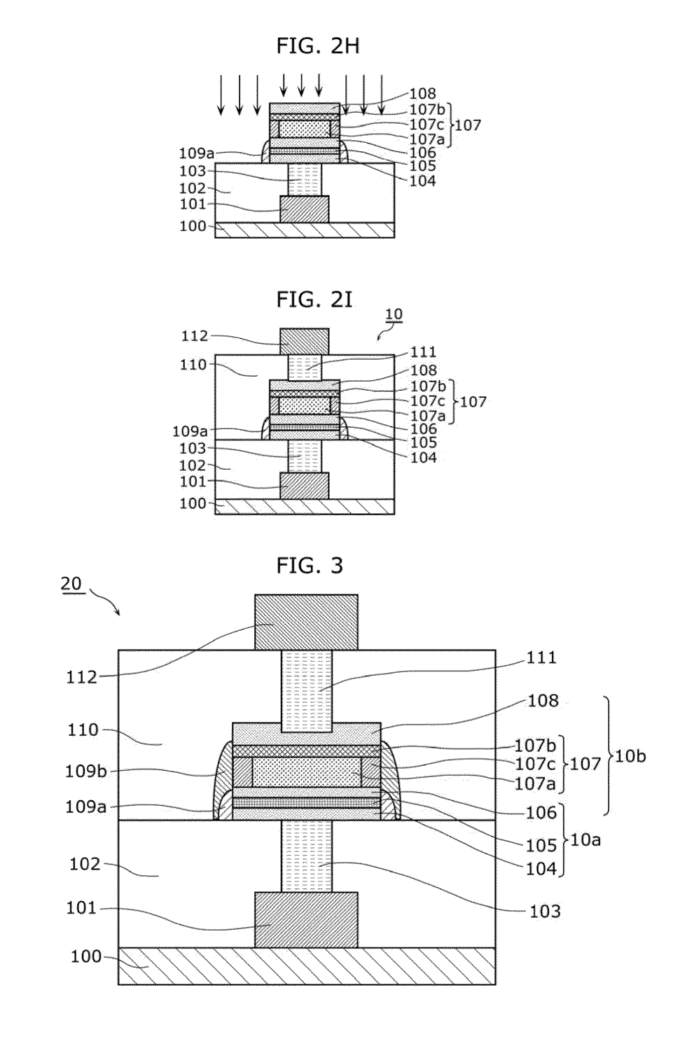

Next, a method of manufacturing the variable resistance nonvolatile memory device 10 according to this embodiment is described. Each of FIG. 2A to FIG. 2I is a cross-sectional view showing a method of manufacturing a variable resistance nonvolatile semiconductor memory device according to Embodiment 1.

First, as shown in FIG. 2A, the substrate 100 on which a transistor, a lower layer line, and so on (not shown) are formed is prepared (a process of preparing a substrate). The first line 101 is formed by forming, on the substrate 100, a conductive layer comprising aluminum and then patterning the conductive layer. Next, an insulating film is formed on the substrate 100 to cover the first line 101, and then the surface of the insulating film is planarized to form the first interlayer insulating layer 102 (a process of forming the interlayer insulating layer).

Subsequently, as shown in FIG. 2B, the first contact plug 103 is formed which penetrates the first interlayer insulating layer 102, and is electrically connected to the first line 101.

Subsequently, as shown in FIG. 2C, a first conductive film 104′ comprising a tantalum nitride, a semiconductor film 105′ including a nitrogen-deficient silicon nitride film, a second conductive film 106′ comprising a tantalum nitride are formed on the first interlayer insulating layer 102 in this order to cover the first contact plug 103.

Subsequently, as shown in FIG. 2D, a first variable resistance film 107a′ and a second variable resistance film 107b′ each comprising a transition metal oxide, and a third conductive film 108′ comprising a noble metal (platinum, iridium, palladium, or the like) are formed in this order.

Subsequently, using a predetermined mask, as shown in FIG. 2E, the third conductive film 108′, the second variable resistance film 107b′, the first variable resistance film 107a′, the second conductive film 106′, the semiconductor film 105′, and the first conductive film 104′ are each pattered. With this, the MSM diode element 10a including the upper electrode 106, the semiconductor layer 105, and the lower electrode 104 which are stacked in this order is formed above the substrate 100 (a process of forming an MSM diode element). Furthermore, the variable resistance element 10b including the upper electrode 108, the second variable resistance layer 107b, the first variable resistance layer 107a, and the lower electrode 106 which are stacked in this order is formed on the MSM diode element 10a (a process of forming a variable resistance element).

Subsequently, as shown in FIG. 2F, a first oxygen barrier film 109a′ is formed on the first interlayer insulating layer 102 to cover the MSM diode element 10a and the variable resistance element 10b. The first oxygen barrier film 109a′ comprises a silicon nitride (SiN), a silicon oxynitride (SiON), or the like. A chemical vapor deposition (CVD) method or an atomic layer deposition (ALD) method may be used as the film formation method to ensure that the first oxygen barrier film 109a′ is sufficiently formed on edge part of the variable resistance nonvolatile memory device 10 as well.

Subsequently, as shown in FIG. 2G, etch-back is performed on the entire surface of the first oxygen barrier film 109a′ to remove the first oxygen barrier film 109a′ on the first interlayer insulating layer 102 and on the upper electrode 108 of the variable resistance element 10b. With this, the first oxygen barrier layer 109a in a side wall shape is formed to cover the side wall of the semiconductor layer 105 of the MSM diode element 10a (a process of forming the first oxygen barrier layer). At this time, the top position of the first oxygen barrier layer 109a is adjusted with an etching time to achieve the state in which the side wall of the semiconductor layer 105 is completely covered by the first oxygen barrier layer 109a and at least part of the side wall of the first variable resistance layer 107a is exposed without being covered by the first oxygen barrier layer 109a. Note that, as an etching gas used in a process shown in FIG. 2G, a fluorine-containing gas can be used which can provide a sufficient etching rate and a selectivity ratio to a metal material included in the upper electrode 108.

Note that, the first oxygen barrier layer 109a is formed to cover the entire side wall of the semiconductor layer 105 to prevent the semiconductor layer 105 from oxidizing in a manufacturing process (a process shown in FIG. 2H) which will be described later. Furthermore, when the upper electrode 106 of the MSM diode element 10a comprises an easily oxidizable material, it is also possible to form the first oxygen barrier layer 109a to cover, in addition to the entire side wall of the semiconductor layer 105, the interface between the semiconductor layer 105 and the upper electrode 106.

Furthermore, in order to insulate the side wall of the first variable resistance layer 107a by oxidation in a manufacturing process (the process shown in FIG. 2H) which will be described later, the first oxygen barrier layer 109a is formed without covering at least part of the side wall of the first variable resistance layer 107a. Furthermore, the first oxygen barrier layer 109a can also be formed without covering the entirety of the side wall of the first variable resistance layer 107a.

Subsequently, as shown in FIG. 2H, annealing in an oxygen atmosphere with a temperature of 300 to 450 degrees Celsius is performed in a state where the semiconductor layer 105 of the MSM diode element 10a is covered by the first oxygen barrier layer 109a. The side wall of the first variable resistance layer 107a is thus oxidized, forming the third variable resistance layer 107c to process of oxidizing the side wall of the variable resistance layer). With this, the side wall of the first variable resistance layer 107a is insulated by oxidation. Note that, the second variable resistance layer 107b is hardly oxidized, when the second variable resistance layer 107b is practically an insulating later from the start.

When an oxidation process (oxygen anneal) is performed in the process shown in FIG. 2H, the first oxygen barrier layer 109a serves as an oxygen barrier, and thus the side wall of the semiconductor layer 105 of the MSM diode element 10a is not oxidized. Note that, an oxide layer (not shown) is formed on the surface of the first oxygen barrier layer 109a by the above-described oxidation process.

Subsequently, as shown in FIG. 2I, the second interlayer insulating layer 110 is formed to cover the MSM diode element 10a and the variable resistance element 10b (a process of forming an interlayer insulating layer). Subsequently, the second contact plug 111 is formed which penetrates the second interlayer insulating layer 110 and is electrically connected to the upper electrode 108. Subsequently, the second line 112 is formed which is electrically connected to the second contact plug 111. The variable resistance nonvolatile memory device 10 according to this embodiment is manufactured as above.

In this embodiment, the side wall of the semiconductor layer 105 of the MSM diode element 10a is covered by the first oxygen barrier layer 109a. Thus, it is possible to prevent the side wall of the semiconductor layer 105 from oxidizing when oxidizing the side wall of the first variable resistance layer 107a. This makes it possible to simultaneously achieve two advantageous effects which are (i) lowering of the initial breakdown voltage and reduction in the application time of the initial breakdown voltage, and (ii) prevention of deterioration of the driving capability of the MSM diode element 10a, in particular, this embodiment can significantly contribute to miniaturization and increase in the capacity of a cross-point memory which uses the MSM diode element 10a.

### Embodiment 2

### Configuration of Variable Resistance Nonvolatile Memory Device

FIG. 3 is cross-sectional view showing a configuration of a variable resistance nonvolatile memory device according to Embodiment 2. As shown in FIG. 3, in a variable resistance nonvolatile memory device 20 according to this embodiment, in addition to the first oxygen barrier layer 109a described in Embodiment 1, a second oxygen barrier layer 109b is formed to cover the side wall (outer periphery part) of a second variable resistance layer 107b and the side wall (outer periphery part) of a third variable resistance layer 107c. The second oxygen barrier layer 109b comprises, for example, a material, such as a silicon nitride (SiN), or a silicon oxynitride (SiON), which serves as an oxygen barrier that prevents external oxygen from diffusing into the variable resistance layer 107.

(Manufacturing Method)

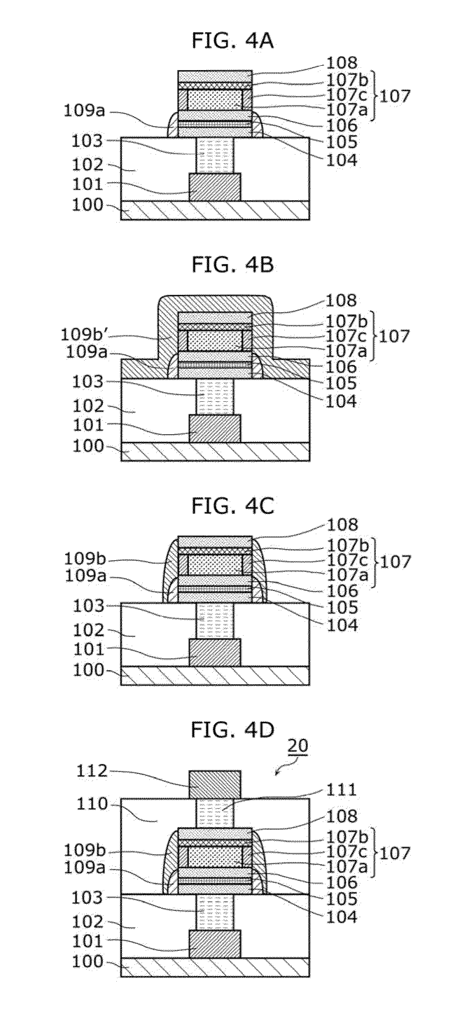

Next, a method of manufacturing the variable resistance nonvolatile memory device 20 is described. FIG. 4A to FIG. 4D are cross-sectional views showing parts of a method of manufacturing the variable resistance nonvolatile memory device according to Embodiment 2.

First, before a process shown in FIG. 4A, processes shown in FIG. 2A to FIG. 2G described above are performed. The processes shown in FIG. 2A to FIG. 2G are similar to the above description, and thus the descriptions thereof are omitted.

Subsequently, as shown in FIG. 4A, annealing in an oxygen atmosphere with a temperature of 300 to 450 degrees Celsius is performed in a state where the semiconductor layer 105 of the MSM diode element 10a is covered by the first oxygen barrier layer 109a. The side wall of the first variable resistance layer 107a is thus oxidized, forming the third variable resistance layer 107c (a process of oxidizing the side wall of the variable resistance layer). With this, the side wall of the first variable resistance layer 107a is insulated by oxidation. Note that, the second variable resistance layer 107b is hardly oxidized, when the second variable resistance layer 107b is practically an insulating later from the start.

As described above, the first oxygen barrier layer 109a serves as the oxygen barrier, and thus the side wall of the semiconductor layer 105 of the MSM diode element 10a is not oxidized at the time when an oxidation process is performed in a process shown in FIG. 2G. Note that, an oxide layer (not shown) is formed on the surface of the first oxygen barrier layer 109a by the above-described oxidation process.

Subsequently, as shown in FIG. 4B, a second oxygen barrier film 109b′ is formed on the first interlayer insulating layer 102 to cover (i) a stacked structure including the MSM diode element 10a and the variable resistance element 10b, and (ii) the first oxygen barrier layer 109a. The second oxygen barrier film 109b′ comprises a silicon nitride (SiN), a silicon oxynitride (SiON), or the like. A DID method or an ALD method may be used as the film formation method to ensure that the second oxygen barrier film 109b′ is formed on edge part of the variable resistance nonvolatile memory device 20 as well.

Subsequently, as shown in FIG. 4C, an etch-back is performed on an entire surface of the second oxygen barrier film 109b′ to remove the second oxygen barrier film 109b′ disposed on the first interlayer insulating layer 102 and on the upper electrode 108 of the variable resistance element 10b. With this, on the first oxygen barrier layer 109a, the second oxygen barrier layer 109b in a side wall shape is formed to cover the side wall of the second variable resistance layer 107b and the side wall of the third variable resistance layer 107c (a process of forming a second oxygen barrier layer). At this time, a top position of the second oxygen barrier layer 109b is adjusted with an etching time to achieve the state in which the side wall of the second variable resistance layer 107b and the side wall of the third variable resistance layer 107c are covered by the second oxygen barrier layer 109b. As an etching gas used in a process shown in FIG. 4C, a fluorine-containing gas can be used which can provide a sufficient etching rate and a selectivity ratio to a metal material included in the upper electrode 108.

Note that, the second oxygen barrier layer 109b can be formed to completely cover the side wall of the third variable resistance layer 107c. Furthermore, it is also possible to form the second oxygen barrier layer 109b to completely cover the side wall of the second variable resistance layer 107b and the side wall of the third variable resistance layer 107c.

Subsequently, as shown in FIG. 4D, the second interlayer insulating layer 110 is formed to cover the MSM diode element 10a and the variable resistance element 10b (a process of forming an interlayer insulating layer). Subsequently, the second contact plug 111 is formed which penetrates the second interlayer insulating layer 110 and is electrically connected to the upper electrode 108. Subsequently, the second line 112 which is electrically connected to the second contact plug 111 is formed. The variable resistance nonvolatile memory device 20 according to this embodiment is thus manufactured.

In this embodiment, in addition to advantageous effects produced by Embodiment 1, the following advantageous effects can be produced. That is, since the second oxygen barrier layer 109b is formed to cover the side wall of the second variable resistance layer 107b and the side wall of the third variable resistance layer 107c, diffusion of external oxygen into the variable resistance layer 107 via the second interlayer insulating layer 110, or the like, can be prevented. With this, it is possible to reduce variation in the side wall oxidation amount of the variable resistance layer 107, and stabilize the side wall oxidation amount of the variable resistance layer 107. The stabilization in the side wall oxidation amount of the variable resistance layer 107 reduces variations in an active area of the variable resistance element 10b narrowed down by the side wall oxidation. Thus, it is possible to reduce variation in a current density at the time of the initial breakdown, allowing for reduction of variation in a magnitude and application time of the initial breakdown voltage.

Note that, the second oxygen barrier layer 109b can also be formed to cover the first oxygen barrier layer 109a. With this, the semiconductor layer 105 of the MSM diode element 10a is doubly covered by the first oxygen barrier layer 109a and the second oxygen barrier layer 109b. Thus, in a manufacturing process in a process shown in FIG. 4C and the subsequent processes, diffusion of external oxygen into the semiconductor layer 105 of the MSM diode element 10a can be prevented even more reliably.

Although Embodiments 1 and 2 of the present invention have thus far been described, the present invention is not limited to these Embodiments 1 and 2. Various improvements, modifications, correction, and combinations can be conceived which do not depart from the essence of the present invention.

The upper electrode (fourth electrode) of the MSM diode element and the lower electrode (first electrode) of the variable resistance element, which are formed as the same electrode that serves as a shared electrode in the above-described Embodiments 1 and 2, may be separate bodies. In other words, the upper electrode of the MSM diode element and the lower electrode of the variable resistance element may be provided separately. In this case as well, as described in Embodiments 1 and 2, the first oxygen barrier layer 109a may be formed without covering at least part of the side wall of the first variable resistance layer 107a.

Furthermore, although the variable resistance layer in each of the above-described Embodiments 1 and 2 has a stacked structure including the first variable resistance layer and the second variable resistance layer, the variable resistance layer can have a single-layer structure.

### INDUSTRIAL APPLICABILITY

The present invention provides a method of manufacturing a variable resistance nonvolatile semiconductor memory device, and the variable resistance nonvolatile semiconductor memory device, and is useful for various electronic devices or the like using a nonvolatile memory.

### REFERENCE SIGNS LIST

10, 20, 50 Variable resistance nonvolatile memory device
10a, 50a MSM diode element
10b, 50b Variable resistance element
100, 500 Substrate
101, 501 First line
102, 502 First interlayer insulating layer
103, 503 First contact plug
104 Lower electrode (third electrode)
104′, 504′ First conductive film
105, 505 Semiconductor layer
105′, 505′ Semiconductor film
106 Upper electrode (lower electrode, first electrode, fourth electrode)
106′, 506′ Second conductive film
107, 507 Variable resistance layer
107a, 507a First variable resistance layer
107a′, 507a′ First variable resistance film
107b, 507b Second variable resistance layer
107b′, 507b′ Second variable resistance film
107c, 507c Third variable resistance layer
108 Upper electrode (second electrode)
108′, 508′ Third conductive film
109a First oxygen barrier layer
109a′ First oxygen barrier film
109b Second oxygen barrier layer
109b′ Second oxygen barrier film
110, 510 Second interlayer insulating layer
111, 511 Second contact plug
112, 512 Second line
504 Lower electrode
505a Side wall
506 Upper electrode (lower electrode)
508 Upper electrode

1-22. (canceled)

23. A method of manufacturing a variable resistance nonvolatile memory device, comprising:
forming, above a substrate, a diode element including a semiconductor layer;
forming a variable resistance element by stacking, on the diode element, a first electrode, a variable resistance layer, and a second electrode in this order;
forming a first oxygen barrier layer which covers a side wall of the semiconductor layer of the diode element, and does not cover at least part of a side wall of the variable resistance layer of the variable resistance element, the first oxygen barrier layer being for preventing the side wall of the semiconductor layer of the diode element from oxidizing; and
oxidizing the side wall of the variable resistance layer which is exposed without being covered by the first oxygen barrier layer.

24. The method according to claim 23,
wherein the side wall of the variable resistance layer is insulated in the oxidizing of the side wall of the variable resistance layer.

25. The method according to claim 23, further comprising
forming, after the oxidizing of the side wall of the variable resistance layer, a second oxygen barrier layer which covers the side wall of the variable resistance layer.

26. The method according to claim 25,
wherein the second oxygen barrier layer prevents external oxygen from diffusing into the side wall of the variable resistance layer.

27. The method according to claim 25,
wherein the second oxygen barrier layer further covers the first oxygen barrier layer.

28. The method according to claim 23, further comprising
forming an interlayer insulating layer to cover the diode element and the variable resistance element.

29. The method according to claim 23,
wherein the variable resistance layer formed in the forming of a variable resistance element includes a first variable resistance layer comprising a first metal oxide, and a second variable resistance layer comprising a second metal oxide having a degree of oxygen deficiency lower than a degree of oxygen deficiency of the first metal oxide.

30. The method according to claim 23,
wherein the variable resistance layer comprises a transition metal oxide or an aluminum oxide.

31. The method according to claim 23,
wherein the diode element is a metal-semiconductor-metal (MSM) diode element formed by:
forming a third electrode above the substrate;
forming the semiconductor layer on the third electrode; and
forming a fourth electrode on the semiconductor layer.

32. The method according to claim 31,
wherein the first electrode and the fourth electrode are formed as a same electrode which serves as a shared electrode.

33. A variable resistance nonvolatile memory device comprising:
a substrate;
a diode element which is formed above the substrate, and includes a semiconductor layer; and
a variable resistance element which is formed on the diode element, and includes a variable resistance layer,
wherein the variable resistance element includes:
a first electrode;
a second electrode disposed opposite the first electrode;
the variable resistance layer disposed between the first electrode and the second electrode; and
a first oxygen barrier layer which covers a side wall of the semiconductor layer of the diode element, and does not cover at least part of a side wall of the variable resistance layer of the variable resistance element, the first oxygen barrier layer being for preventing the side wall of the semiconductor layer of the diode element from oxidizing, and
a region of the side wall of the variable resistance layer of the variable resistance element not covered by the first oxygen barrier layer is insulated.

34. The variable resistance nonvolatile memory device according to claim 33,
wherein the variable resistance element further includes a second oxygen barrier layer which covers the side wall of the variable resistance layer which is oxidized.

35. The variable resistance nonvolatile memory device according to claim 34,
wherein the second oxygen barrier layer prevents external oxygen from diffusing into the side wall of the variable resistance layer.

36. The variable resistance nonvolatile memory device according to claim 34,
wherein the second oxygen barrier layer further covers the first oxygen barrier layer.

37. The variable resistance nonvolatile memory device according to claim 33,
wherein an oxide layer is formed on a surface of the first oxygen barrier layer.

38. The variable resistance nonvolatile memory device according to claim 33,
wherein the variable resistance layer comprises a transition metal oxide or an aluminum oxide.

39. The variable resistance nonvolatile memory device according to claim 38,
wherein the variable resistance layer comprises a transition metal oxide selected from tantalum, hafnium, and zirconium.

40. The variable resistance nonvolatile memory device according to claim 33,
wherein the variable resistance layer of the variable resistance element includes a first variable resistance layer comprising a first metal oxide, and a second variable resistance layer comprising a second metal oxide having a degree of oxygen deficiency lower than a degree of oxygen deficiency of the first metal oxide.

41. The variable resistance nonvolatile memory device according to claim 33,
wherein the diode element is an MSM diode element which includes:
a third electrode formed above the substrate;
a fourth electrode disposed opposite the third electrode; and
the semiconductor layer disposed between the third electrode and the fourth electrode.

42. The variable resistance nonvolatile memory device according to claim 41,
wherein the first electrode and the fourth electrode are a same electrode which serves as a shared electrode.
